(19) United States
(12) Patent Application Publication
(10) Pub. No.: US 2006/0187988 A1
(43) Pub. Date: Aug. 24, 2006

(54) Semiconductor Laser Device

(75) Inventor: Akira TANAKA, Tokyo (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: KABUSHIKI KAISHA TOSHIBA, Tokyo (JP)

(21) Appl. No.: 11/276,240

(22) Filed: Feb. 20, 2006

(30) Foreign Application Priority Data
Feb. 21, 2005 (JP) 2005-044729

(51) Int. Cl. H01S 5/20; H01S 5/00

(52) U.S. Cl. 372/45.01; 372/46.01

(57) ABSTRACT

In various aspects, a semiconductor laser device may include a first clad layer of a first conductivity type having a nitride semiconductor; an active layer provided on the first clad layer and having a nitride semiconductor; a second clad layer of a second conductivity type provided on the active layer having a nitride semiconductor, the second clad layer having a ridge waveguide and a side portion provided in both sides of the ridge waveguide; an upper electrode provided on the ridge waveguide; and a dielectric layer provided on a side surface of the ridge waveguide, wherein the side portion of the second clad layer has a lower activation ratio of a second conductivity type impurity than the ridge waveguide of the second clad layer.

### CROSS REFERENCE TO RELATED APPLICATION

This application is based upon and claims the benefit of priority from Japanese Patent Application No. 2005-44729, filed on Feb. 21, 2005, the entire contents of which are incorporated herein by reference.

### BACKGROUND OF THE INVENTION

Research and development of semiconductor laser devices for next generation DVDs is proceeding. Generally, a semiconductor laser, which emits 400 nm band wavelength laser, is used. InGaAlN semiconductors are expected to be used in semiconductor laser devices for next generation DVDs.

In a conventional InGaAlN semiconductor laser, a double hetero junction is provided on a substrate and a ridge waveguide, which is formed in an upper clad layer, is provided.

A P⁺-type overflow blocking layer, in which high concentrated Mg as a P-type impurity is doped, may be provided between an MQW active layer and a P-type clad layer in the conventional InGaAlN semiconductor laser. The P⁺-type overflow blocking layer prevents electrons from flowing from an N side electrode and promotes a recombination of the electrons and holes in the active layer. However, the overflow blocking layer is a barrier to holes flowing from a P side electrode. So it may be easy for the hole current to be increased from the ridge waveguide to a horizontal direction (away from the ridge waveguide). An oscillation efficiency may be worsened and a threshold current may be increased.

On the other hand, in case electrodes are sintered in a hydrogen ambient, hydrogen atoms are introduced into a P-type clad layer or a P-type contact layer by passing through the dielectric layer provided on the clad layer. The introduced hydrogen worsens activation ratio of the doped Mg. So the resistance may be increased and operating voltage may be increased.

### SUMMARY

Aspects of the invention relate to an improved semiconductor laser device. Other aspects relate to a process for making an improved semiconductor laser device.

### BRIEF DESCRIPTIONS OF THE DRAWINGS

FIG. 1 is a cross sectional view of a semiconductor laser device in accordance with a first embodiment of the present invention.

FIG. 2A is a cross sectional view similar to the FIG. 1. FIG. 2B is a graph showing a distribution of an activation ratio of P-type impurities in P-type semiconductor layers.

FIG. 3A is a cross sectional view similar to the FIG. 1. FIG. 3B is a graph showing a distribution of a content ratio of H in P-type semiconductor layers.

FIG. 4 is a cross sectional view of a semiconductor laser device in accordance with a second embodiment of the present invention.

FIGS. 5-13 are perspective views of a semiconductor laser device showing a manufacturing process in accordance with a second embodiment of the present invention.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

General Overview

In one aspect of the present invention, a semiconductor laser device may include a semiconductor laser device having a first clad layer of a first conductivity type having a nitride semiconductor; an active layer provided on the first clad layer and having a nitride semiconductor; a second clad layer of a second conductivity type provided on the active layer having a nitride semiconductor, the second clad layer having a ridge waveguide and a side portion provided in both sides of the ridge waveguide; an upper electrode provided on the ridge waveguide; and a dielectric layer provided on a side surface of the ridge waveguide; wherein the side portion of the second clad layer has a lower activation ratio of a second conductivity type impurity than the ridge waveguide of the second clad layer.

In another aspect of the invention, a semiconductor laser device may include a first clad layer of a first conductivity type having a nitride semiconductor; an active layer provided on the first clad layer and having a nitride semiconductor; a second clad layer of a second conductivity type provided on the active layer having a nitride semiconductor, the second clad layer having a ridge waveguide and a side portion provided in a side of the ridge waveguide; an upper electrode provided on the ridge waveguide; and a dielectric layer provided on a side surface of the ridge waveguide; wherein the side portion of the second clad layer has a higher content ratio of hydrogen than the ridge waveguide of the second clad layer.

In another aspect of the invention, a semiconductor laser device may include a first clad layer of a first conductivity type having a nitride semiconductor; an active layer provided on the first clad layer and having a nitride semiconductor; a second clad layer of a second conductivity type provided on the active layer having a nitride semiconductor, the second clad layer having a ridge waveguide and a side portion provided in a side of the ridge waveguide; an upper electrode provided on the ridge waveguide; and a dielectric layer provided on a side surface of the ridge waveguide; wherein an upper edge of the dielectric layer is provided higher than an upper edge of the ridge waveguide of the second clad layer.

These and other aspects of the present invention are described below.

### First Embodiment

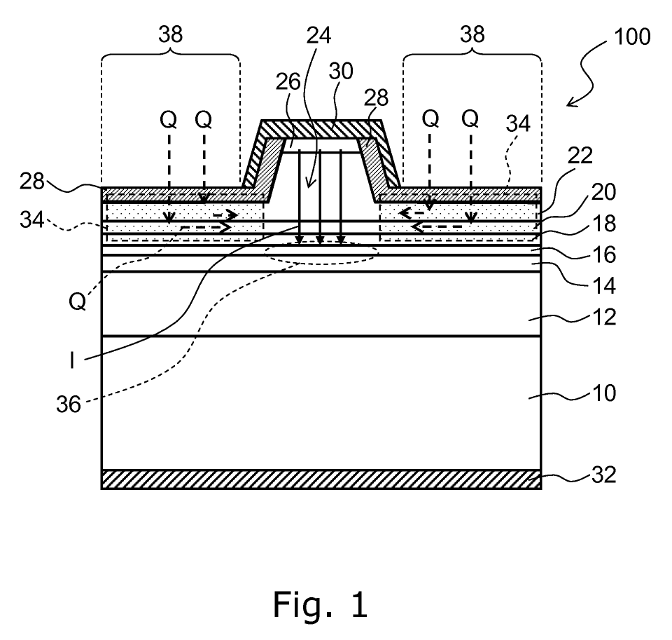

A first embodiment of the present invention will be explained hereinafter with reference to FIGS. 1-3.

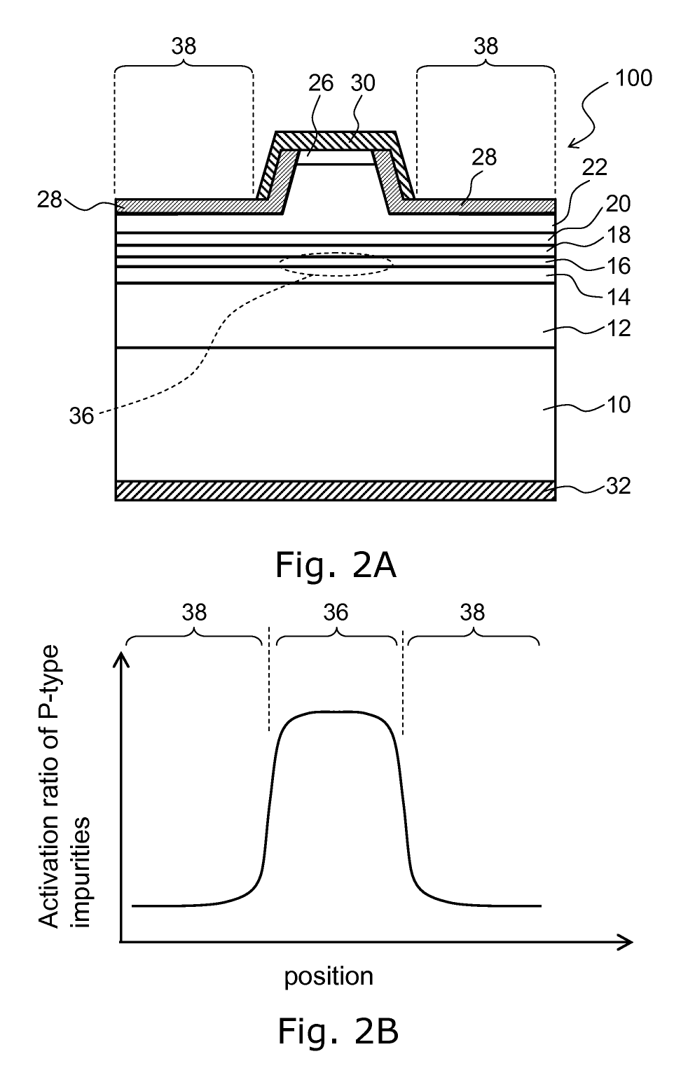

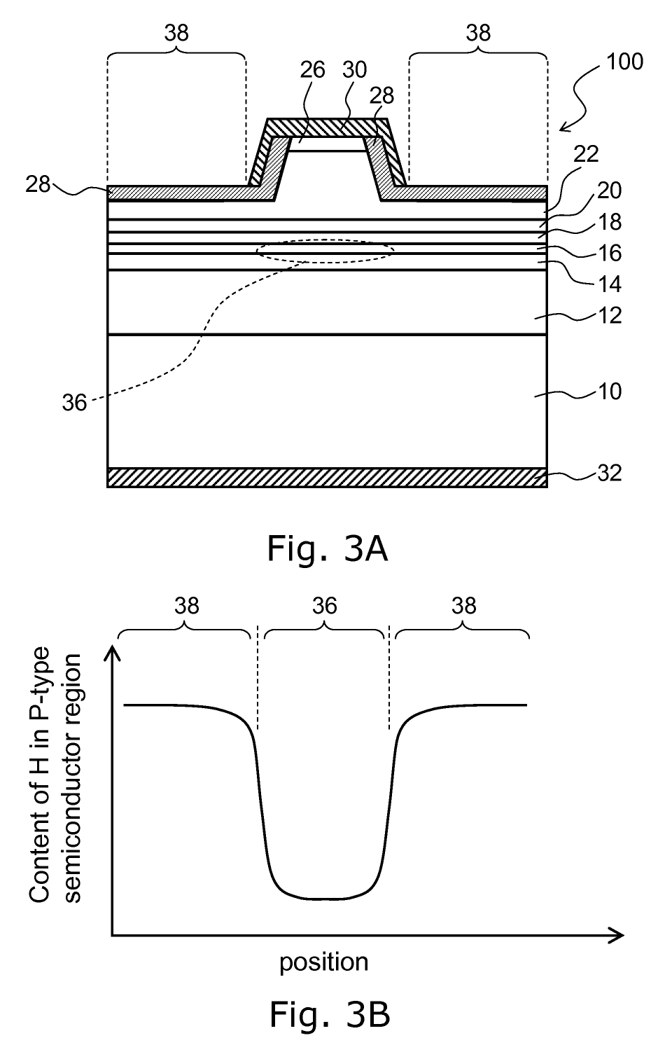

FIG. 1 is a cross sectional view of a semiconductor laser device 100 in accordance with a first embodiment of the present invention. FIG. 2A is a cross sectional view similar to the FIG. 1. FIG. 2B is a graph showing a distribution of an activation ratio of P-type impurities in P-type semiconductor layers. FIG. 3A is a cross sectional view similar to the FIG. 1. FIG. 3B is a graph showing a distribution of a content ratio of H (hydrogen) in P-type semiconductor layers.

In the semiconductor laser device 100, an N-type AlGaN clad layer 12, a N-type GaN optical guide layer 14, an active layer 16, a P+-type AlGaN overflow blocking layer 18, a P-type GaN optical guide layer 20 and a P-type AlGaN clad layer 22 are provided on an N-type GaN substrate 10 in this order. In the P-type clad layer 22, a ridge waveguide 24, which has a stripe shape portion, is provided. A dielectric layer 28, which has lower refractive index than the ridge waveguide 24, is provided on a side surface of the ridge waveguide 24. An upper electrode 30 (P side electrode) is provided on top of the ridge waveguide 24 via a contact layer 26. A bottom electrode 32 (N side electrode) is provided on a bottom surface of the substrate 10.

The upper electrode 30 may be provided on the side surface of the ridge waveguide 24 via a dielectric layer 28 as shown in FIG. 1. The contact layer 26 may be removed if the carrier concentration of the ridge waveguide is high.

Laser oscillation occurs in the cavity created by an emission surface and its opposite surface, when current is injected between the upper electrode 30 and the bottom electrode 32 and the active layer 16 is excited. Light is confined vertically in the active layer 16 by the clad layers 12 and 22, which have different refractive indices. Light is confined horizontally by the dielectric layer 28, which is provided on a side surface of the ridge waveguide 24. Laser light is emitted from a light emitting portion 36 and spreads horizontally and vertically. A structure of the semiconductor laser device 100 is a kind of a refractive index guide type laser. The light emitting portion 36 is provided under the ridge waveguide 24.

A side portion 38 is provided in the semiconductor laser emitting device 100. A H (hydrogen) introduced region 34, where the hydrogen is introduced, is provided in the side portion 38. The hydrogen may be introduced as shown by arrow Q in FIG. 1. The hydrogen passes through the dielectric layer 28 and permeates the dielectric layer 28. In case a conductivity type of a clad layer constituting the ridge waveguide 24 is a P-type, a P-type impurity such as Mg contained in the clad layer is bound to the hydrogen atom. So Mg—H combination is created and the P-type impurity, Mg, is deactivated. The hydrogen may be diffused to the ridge waveguide structure 24 after heat treatment is provided.

In this embodiment, the hydrogen introduced region 34 is provided in a part of the overflow blocking layer 18, the optical guide layer 20, and the clad layer 22.

In case the hydrogen is introduced in a P-type region, an activation ratio of the P-type impurity is worsened, since the hydrogen binds to the P-type impurity in the P-type region and the P-type impurity is deactivated. In case the activation ratio of the P-type impurities is low, the resistance in the P-type region is increased.

In this embodiment, the hydrogen is introduced in a part of the overflow blocking layer 18, the optical guide layer 20 and the clad layer 22, which is under the side portion 38. So the resistance of that part is higher than that of the ridge waveguide 24.

The hydrogen is introduced in the P-type 22 clad layer of the side portion 38. A part of the hydrogen may be diffused toward the ridge waveguide 24.

FIG. 2A is a cross sectional view similar to the FIG. 1. FIG. 2B is a graph showing a distribution of an activation ratio of P-type impurities in P-type semiconductor layers. FIG. 3A is a cross sectional view similar to the FIG. 1. FIG. 3B is a graph showing a distribution of a content ratio of H in P-type semiconductor layers.

As shown in these graphs, the P-type clad layer 22, the P-type optical guide layer 20, and the overflow blocking layer 18 provided on the light emitting portion 36 have a low hydrogen content ratio and a high activation ratio of the P-type impurities.

On the other hand, the P-type clad layer 22, the P-type optical guide layer 20, and the overflow blocking layer 18 provided in the side portion 38 have a high hydrogen content ratio and a low activation ratio of the P-type impurities.

It is preferable that an activation ratio of the P-type impurity of the P-type clad layer 22, the P-type optical guide layer 20 and the overflow blocking layer 18 provided on the light emitting portion 36 is 7% or more. On the other hand, an activation ratio of the P-type impurity of the P-type clad layer 22, the P-type optical guide layer 20, and the overflow blocking layer 18 provided in the side portion 38 is less than 7%. This activation ratio is capable of being obtained by selecting a suitable crystal growing condition. This technique is shown in, for example, Japanese Patent No. 2919788.

In the side portion 38, a resistance value is high. As shown in FIG. 1, the current I injected from the ridge waveguide 24 hardly flows in the horizontal direction, since the hydrogen introduced region 34 having a high resistance is provided. So the current I is concentrated in a region under the ridge waveguide 24. In other words, the current I is confined by the hydrogen introduced region 34.

If the hydrogen introduced region 34 is not provided in the semiconductor laser device 100, a hole is spread horizontally by the overflow blocking layer 18, which functions as a potential barrier. Light output efficiency is worsened and the threshold voltage is increased.

However, in this embodiment, current spreading in a horizontal direction is restricted by the hydrogen introduced region 34. Light output efficiency is improved and the threshold voltage is decreased.

In this embodiment, it is not necessary that all of the P-type clad layer 22, P-type optical guide layer 20, and overflow blocking layer 18 has a characteristic shown in FIGS. 2B and 3B. In some aspects, only the P-type clad layer 22 may have a characteristic shown in FIGS. 2B and 3B.

A structure of the semiconductor laser device is explained in detail.

The N-type Al_{0.05}Ga_{0.95}N clad layer 12 (thickness 0.5˜2.0 μm), the N-type GaN optical guide layer 14 (thickness 0.01-0.10 μm), In_{0.15}Ga_{0.85}N/In_{0.02}Ga_{0.98}N MQW (Multiple Quantum Well) active layer 16 (thickness of well layer 2˜5 nm, the number of wells 2-4, thickness of barrier layer 3-10 nm), the P⁺-type Al_{0.2}Ga_{0.8}N overflow blocking layer 18 (thickness 5-20 nm), the P-type GaN optical guide layer 20 (thickness 0.01-0.10 μm), the P-type Al_{0.05}Ga_{0.95}N clad layer 22 (0.5-2.0 μm), the P⁺-type GaN contact layer 26 (thickness 0.02-0.2 μm) are provided on the N-type GaN substrate 10 in this order. The ridge waveguide structure 24, which confines light in horizontal direction, is provided in the P-type A1GaN clad layer 22.

In order to obtain a low threshold current in the semiconductor laser device 100, the optical energy is confined between the GaN optical guide layers 14 and 20.

The P+-type overflow blocking layer 18, in which P-type impurity such as Mg is doped, is configured to block overflowing electron flow from the substrate side and reduce current increasing in a high temperature.

The dielectric layer 28 has a low refractive index than the ridge waveguide 24. For example, the dielectric layer 28 may be made of SiO2 or SiN.

The upper electrode 30 may be a metal, which is capable of absorbing hydrogen, such as a single layer, multilayer or an alloy of Ti, V, Nb, Ta, Pd, Er.

The bottom electrode 32 may be a single layer, multilayer or an alloy of Ti, Pt, Au, Al.

In case such a metal, which is capable of absorbing hydrogen, is used as the upper electrode 30, it is hard for hydrogen introduced in the later heat treatment process to remain near the contact layer 30. If the electrode 30 is sintered in hydrogen ambient, hydrogen is absorbed by the metal. So the deactivation ratio of a region below the metal is reduced and the semiconductor laser device may have a low operating voltage.

In this embodiment, such a metal, which is capable of absorbing hydrogen, is provided on the ridge waveguide 24, the resistance of the ridge waveguide 24 is lower than the clad layer 22 in the hydrogen introduced region 34.

In this first embodiment, the P-type clad layer 22 of the side portion 38 has a lower activation ratio of the P-type impurity than the P-type clad layer in the ridge waveguide 24. So a resistance in the P-type clad layer 22 of the side portion 38 is higher than a resistance the P-type clad layer 22 in the ridge waveguide 24. Thus the current pass may be narrowed, the threshold current may be reduced, and the optical emission efficiency may be improved.

In this first embodiment, the P-type clad layer in the side portion 38 has a lower content ratio of H (hydrogen) than the P-type clad layer of the ridge waveguide 24. So a resistance in the P-type clad layer of the side portion 38 is higher than a resistance of the P-type clad layer under the ridge waveguide 24. Thus the current pass may be narrowed and the threshold current may be reduced and the optical emission efficiency may be improved.

### Second Embodiment

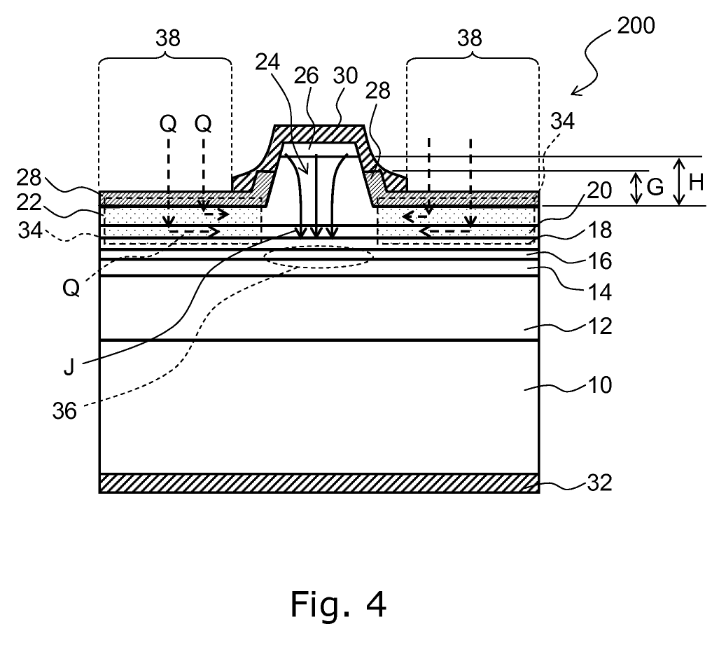

A second embodiment is explained with reference to FIGS. 4-13.

A semiconductor laser device 200 is described in accordance with a second embodiment to the present invention. With respect to each portion of this second embodiment, the same or corresponding portions of the semiconductor laser device of the first embodiment shown in FIGS. 1-3B are designated by the same reference numerals, and explanation of such portions is omitted.

FIG. 4 is a cross sectional view of a semiconductor laser device 200 in accordance with a second embodiment of the present invention.

In this second embodiment, an upper edge of the ridge waveguide 24 is higher than an upper edge of the dielectric layer 28. In other words, a height H of the ridge waveguide 24 is greater than a height G of the dielectric layer 28. A part of a side surface of the ridge waveguide 24 is not covered with the dielectric layer 28. The upper electrode 30 is in contact with the ridge waveguide 24 at the part of the side surface of the ridge waveguide 24.

An operating voltage is decreased by the structure adapted in the semiconductor laser device 200. A current as shown in arrow J is injected from the upper electrode 30, which has a larger contact area with the ridge waveguide 24 than that of the first embodiment. The operating voltage may be decreased, even in case the current is horizontally confined by the hydrogen introduced region 34

In case G/H≦0.7, a contact resistance of the upper electrode 30 is reduced. The height G is designed so as to confine the light horizontally.

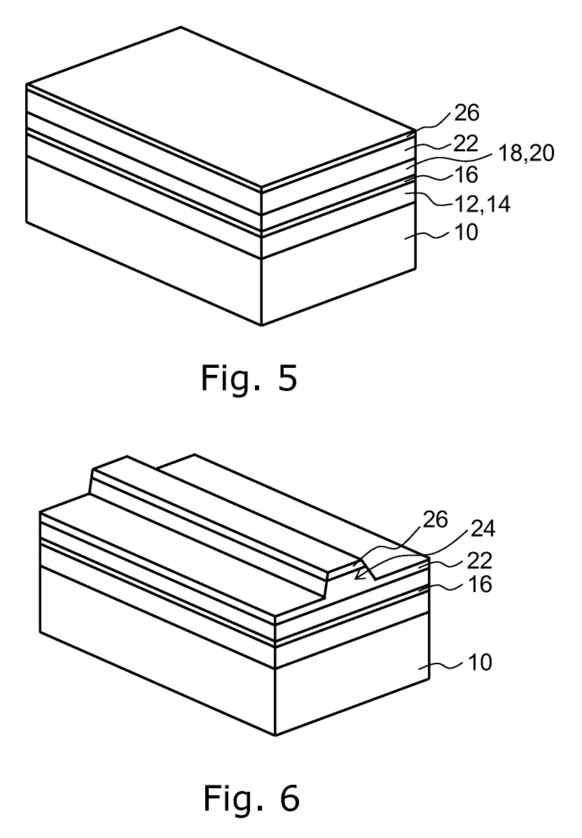

The manufacturing process of the semiconductor laser device in accordance with the second embodiment will be explained hereinafter with reference to FIGS. 5-13.

As shown in FIG. 5, the N-type AlGaN clad layer 12, the N-type GaN optical guide layer 14, the active layer 16, the P⁺-type AlGaN overflow blocking layer 18, the P-type GaN optical guide layer 20, the P-type AlGaN clad layer 22 and the contact layer 26 is grown on the GaN substrate 10 in this order by, for example MOCVD.

As shown in FIG. 6, the P-type AlGaN clad layer 22 and the contact layer 26 are selectively etched so as to form a shaped ridge extending from a front face to a rear face. So the ridge waveguide 24 of the second clad layer 22 and stripe shaped contact layer 26 is created.

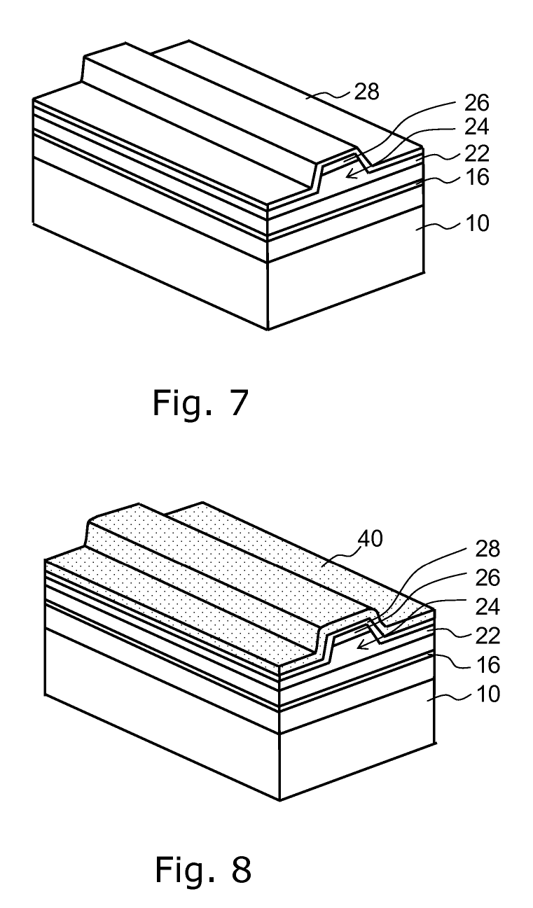

As shown in FIG. 7, the dielectric layer 28 is deposited on an exposed surface of the second clad layer 22 and the contact layer 26. A thickness of the dielectric layer 28 may be b 0.2-0.7 μm.

As shown in FIG. 8, a photoresist 40 is provided on the dielectric layer 28.

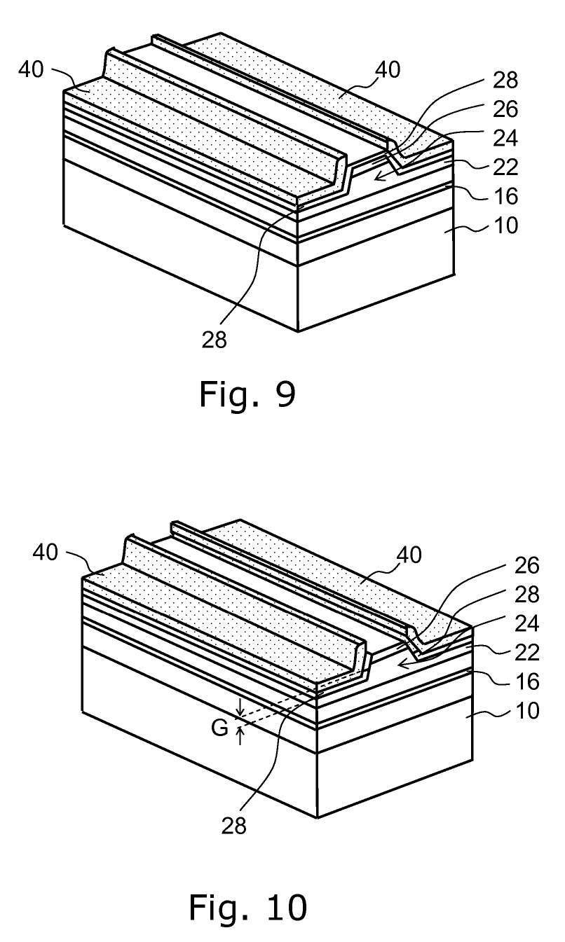

As shown in FIG. 9, the photoresist 40 provided on the contact layer 26 is removed by etching.

As shown in FIG. 10, the dielectric layer 28 provided on the ridge waveguide 24 is etched by, for example, a HF based etchant. The dielectric layer 28 having the height G is provided on the side of the ridge waveguide 24.

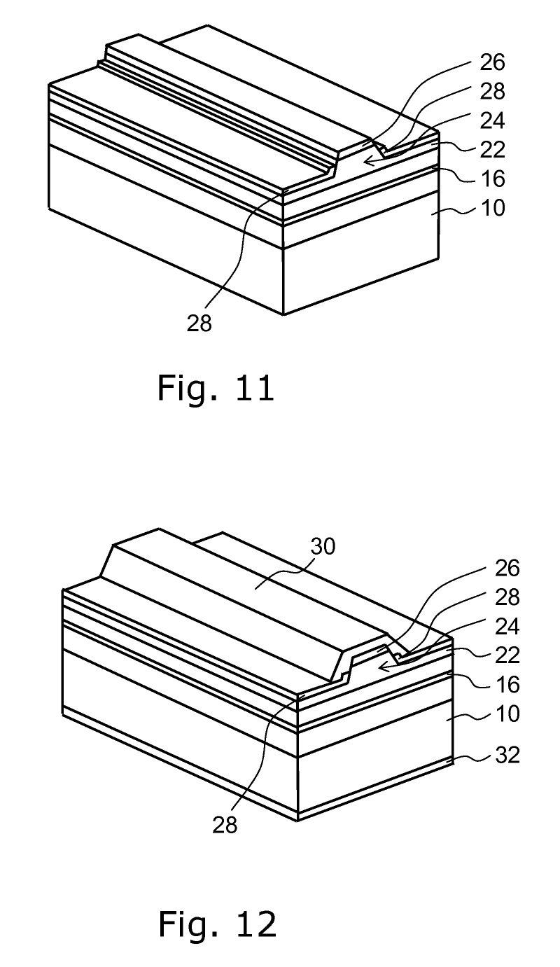

As shown in FIG. 11, the photoresist 40 is removed. The dielectric layer 28 covers the side of the ridge waveguide 24 and the side portion 38 of the P-type clad layer 22.

As shown in FIG. 12, the upper electrode 30 and the bottom electrode 32 is provided. The upper electrode 30 may be a metal, which is capable of absorbing hydrogen, such as single layer, multilayer or alloy of Ti, V, Nb, Ta, Pd, Er, or combination thereof.

In case such a metal is used as the upper electrode 30, it is hard for hydrogen introduced in the later heat treatment process to remain near the contact layer 30. If the electrode 30 is sintered in hydrogen ambient, hydrogen is absorbed by the metal. So the deactivation of region below the metal is reduced and the semiconductor laser device may have a low operating voltage.

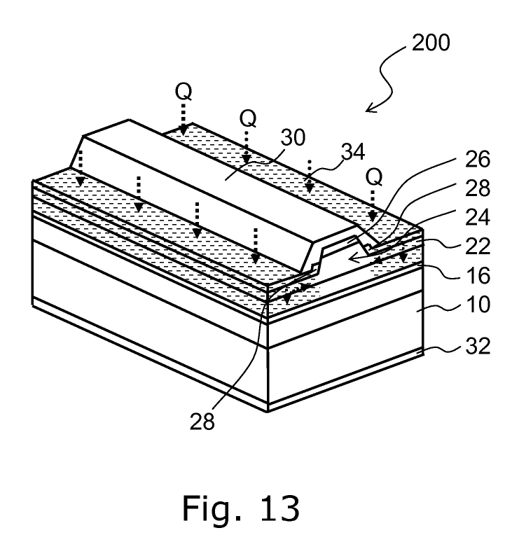

As shown in FIG. 13, heat treatment in an ambient having hydrogen is performed at a temperature range such as 300-500 Centigrade, preferably 370-430 Centigrade. The hydrogen is introduced under a part of the side portion 38, which the upper electrode 30 is not provided on. In the hydrogen introduced region 34, the P-type impurities are deactivated and a resistance is increased. The hydrogen introduced region 34 prevents the current frown from the ridge waveguide 24 from spreading horizontally. Alternatively, the heat treatment process may be operated in a sinter of the upper electrode 30 and the bottom electrode 32.

In the ridge waveguide 24 provided near the upper electrode 30, the deactivation by combining the P-type impurities and hydrogen is reduced, since the hydrogen is absorbed by the upper electrode 30. An increasing of the operating voltage may be reduced. A semiconductor laser device having a low threshold voltage and high emission efficiency may be obtained.

According to a manufacturing process above mentioned, the productivity is high, since the semiconductor layers may be grown continuously.

A manufacturing process is not difficult, since a current flowing from the upper electrode 30 to the active layer 16 may be controllable by heat treatment process after forming the upper electrode 30.

A supplementary explanation of the hydrogen introduced region 34 is described. The P-type impurities of InGaAlN semiconductors are deactivated in hydrogen ambient. In the structure shown in FIGS. 1 and 4, the P+-type AlGaN overflow blocking layer 18, P-type optical guide layer 20 and the P-type clad layer 22 in the side portion 38 are capable of being deactivated. However, it is not necessary that all of the P-type layers are deactivated. If a part of the P-type clad layer 22 is deactivated or is increased in resistance, the current confined passing effect occurs. The position and the area of the hydrogen introduced region 34 may be set in accordance with the required characteristics. The condition of the heat treatment may be set in accordance with the required characteristics.

In these embodiments, the semiconductor laser device is provided on the GaN substrate. However the semiconductor laser device may be provided on sapphire substrate by, for example, ELOG (Epitaxial Lateral Over Growth).

In these embodiments, the deactivated region 344 is spaced from the ridge waveguide 24. However, the deactivated region 34 may abut the ridge waveguide 24 or extend into the ridge waveguide 24.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor laser device, comprising:
a first clad layer of a first conductivity type having a nitride semiconductor;
an active layer provided on the first clad layer and having a nitride semiconductor;
a second clad layer of a second conductivity type provided on the active layer having a nitride semiconductor, the second clad layer having a ridge waveguide and a side portion provided in both sides of the ridge waveguide;
an upper electrode provided on the ridge waveguide; and
a dielectric layer provided on a side surface of the ridge waveguide,
wherein the side portion of the second clad layer has a lower activation ratio of a second conductivity type impurity than the ridge waveguide of the second clad layer.

2. A semiconductor laser device of claim 1, wherein the activation ratio in the ridge waveguide of the second clad layer is no less than 7% and the activation ratio in the side portion of the second clad layer is less than 7%.

3. A semiconductor laser device of claim 1, wherein an upper edge of the dielectric layer is provided higher than an upper edge of the ridge waveguide of the second clad layer.

4. A semiconductor laser device of claim 3, wherein the upper electrode is in contact with a side surface of the ridge waveguide of the second clad layer.

5. A semiconductor laser device of claim 1, wherein the side portion of the second clad layer is higher in content ratio of hydrogen than the ridge waveguide of the second clad layer.

6. A semiconductor laser device of claim 4, wherein the side portion of the second clad layer is higher in content ratio of hydrogen than the ridge waveguide of the second clad layer.

7. A semiconductor laser device, comprising:
a first clad layer of a first conductivity type having a nitride semiconductor;
an active layer provided on the first clad layer and having a nitride semiconductor;
a second clad layer of a second conductivity type provided on the active layer having a nitride semiconductor, the second clad layer having a ridge waveguide and a side portion provided in a side of the ridge waveguide;
an upper electrode provided on the ridge waveguide; and
a dielectric layer provided on a side surface of the ridge waveguide,
wherein the side portion of the second clad layer has a higher content ratio of hydrogen than the ridge waveguide of the second clad layer.

8. A semiconductor laser device of claim 7, wherein an upper edge of the dielectric layer is provided higher than an upper edge of the ridge waveguide of the second clad layer.

9. A semiconductor laser device of claim 8, wherein the upper electrode is in contact with a side surface of the ridge waveguide of the second clad layer.

10. A semiconductor laser device, comprising:
a first clad layer of a first conductivity type having a nitride semiconductor;
an active layer provided on the first clad layer and having a nitride semiconductor;
a second clad layer of a second conductivity type provided on the active layer having a nitride semiconductor, the second clad layer having a ridge waveguide and a side portion provided in a side of the ridge waveguide;
an upper electrode provided on the ridge waveguide; and
a dielectric layer provided on a side surface of the ridge waveguide,
wherein an upper edge of the dielectric layer is provided higher than an upper edge of the ridge waveguide of the second clad layer.

11. A semiconductor laser device of claim 10, wherein the upper electrode is in contact with a side surface of the ridge waveguide of the second clad layer.
